(19) United States
(12) Patent Application Publication
(10) Pub. No.: US 2023/0251293 A1
(43) Pub. Date: Aug. 10, 2023

(54) DEVICE FOR DETERMINING THE ELECTRICAL RESISTANCE OF A SYSTEM, AND ASSOCIATED METHOD

(71) Applicants: CENTRE NATIONAL DE LA RECHERCHE SCIENTIFIQUE, Paris (FR); UNIVERSITE D'AIX-MARSEILLE, MARSEILLE CEDEX 07 (FR)

(72) Inventors: Roger MORIN, MARSEILLE (FR); Alain DEGIOVANNI, MARSEILLE (FR); Laurent LAPENA, MARSEILLE (FR); Evelyne SALANCON, MARSEILLE (FR)

(21) Appl. No.: 18/012,969

(22) PCT Filed: Jun. 30, 2021
(86) PCT No.: PCT/EP2021/068080

§ 371 Date: Dec. 26, 2022

(30) Foreign Application Priority Data
Jul. 10, 2020 (FR) 2007337

(51) Int. Cl. G01R 27/02; G01R 15/26

(52) U.S. Cl. CPC G01R 27/025; G01R 15/26

(57) ABSTRACT

A device for determining the electrical resistance of a system includes a field effect electron emitter capable of emitting electrons when the electrical emission potential Vₑ of the electron emitter is higher than a threshold value V_{L}, with the emitting end of the emitter being at least partially conductive; an item of equipment capable of determining the electrical emission potential Vₑ of the electron emitter; a voltage source adapted to apply a potential difference E to the device and to generate an electric field at the emitter, an electron detector capable of detecting all or some of the electrons emitted by the electron emitter so as to measure the intensity of the current Iₘₑₛ flowing between the emitter and the detector; electrical connection means adapted to electrically connect the system and the device in such a way that the current intensity flowing between the emitter and the detector can also pass through the system.

### TECHNICAL FIELD OF THE INVENTION

The invention relates to the field of measuring electrical variables, more specifically of measuring electrical resistance.

The invention particularly relates to determining very high values of electrical resistance.

### PRIOR ART

Measuring very high electrical resistance values is a key element in manufacturing very high impedance voltmeters or very low current ammeters, as well as in characterizing the electrical insulation materials and the associated devices.

A known principle for measuring a high electrical resistance value of a system involves applying a high voltage to the system for which the resistance is intended to be measured and using a Hall-effect current sensor, such as an amperometric probe or clamp, to measure the intensity and deduce the resistance therefrom. However, the devices implementing this principle do not allow resistance values of more than 10¹⁰ or 10¹¹ Ohms to be measured and certain electrical insulators thus cannot be characterized.

An electrometer device also exists that allows measurements to be carried out with resistance up to 200 Tera Ohms (200 TΩ), that is, 2.10¹⁴ Ohms. This is generally used for electrical insulation measurements. In this type of device, measuring very high resistances is directly related to the use of a stable, very low current source. An electrometer known from Keithley® allows 10fA (10⁻¹⁴ A) to be measured with a sensitivity of 1fA (10⁻¹⁵ A).

However, a device is sought that allows resistance values beyond 200 TΩ to be determined, and which can reach 10²²Ω. However, the limitation of measuring a high resistance value is limited by the thermal noise, even for a device of the electrometer type as described above.

The invention aims to overcome the aforementioned disadvantages of the prior art.

More specifically, it aims to produce a device for measuring the resistance of a system with a very high electrical resistance value, beyond Tera Ohm, or even beyond 10¹⁵ Ohms and able to reach 10²² Ohms.

### DISCLOSURE OF THE INVENTION

A first aim of the invention for addressing these disadvantages is a device for determining the electrical resistance of a system, the device comprising:

a field effect electron emitter capable of emitting electrons (thus generating a current) when the electrical emission potential Vₑ of the electron emitter is higher than a threshold value V_{L}.
an item of equipment capable of determining the electrical emission potential Vₑ of the electron emitter;
a voltage source adapted to apply a potential difference E to the device and to generate an electric field at the emitter;
an electron detector capable of detecting all or some of the electrons emitted by the electron emitter so as to measure the intensity of the current Iₘₑₛ flowing between the emitter and the detector; and
electrical connection means adapted to electrically connect the system for which the electrical resistance is to be determined and the device in such a way that the current flowing between the emitter and the detector can also pass through said system.

According to the present invention, the electrical emission potential can be shortened to “emission potential”.

In general, in the present invention, the term “potential” denotes an electrical potential.

The term “system” in the present invention denotes any component, object, apparatus having electrical connection terminals of the dipole type, and having a very high value electrical resistance.

A field emission (or cold emission) electron emitter is an electron source that comprises an emitter material with geometry or conformation that allows a high electric field to be reached when it is subjected to an electrical potential. Under the effect of such an electric field, electrons pass through a potential barrier by the tunnel effect from the Fermi level, at ambient temperature and are emitted by the material. Applying the electric field to the material can be combined with heating the material, in order to obtain a Schottky emission, which allows the electrical extraction potential of the electrons to be reduced.

The end of the emitter material must be at least partially conductive.

The emitter material generally comprises a conducting wire (metal or semiconductor), an end of which is shaped as a tip. The most common material is tungsten.

The emitter material forms a cathode (generally called “cold cathode”).

In order to extract the electrons from the emitter, the device comprises an electron extractor, with the extractor being disposed between the emitter and the detector. The electron extractor generally comprises an extraction electrode, forming an anode, configured to generate an electric field when an electrical extraction potential is applied thereto. Thus, the electrons are emitted toward said electrode, and are directed toward the detector. The emitter is negatively biased with respect to the extractor. For example, the emitter is negatively biased with respect to the extraction electrode, which is grounded.

As an alternative to an electrode, the extractor can comprise an extraction grid forming an anode.

The term “grid” is understood to mean an electrode having one or more openings for the passage of the electrons.

According to one embodiment, the item of equipment capable of determining the electrical emission potential Vₑ of the electron emitter comprises an energy analyzer.

According to one embodiment, the item of equipment capable of determining the electrical emission potential Vₑ of the electron emitter comprises:

a retarding grid disposed between the emitter and the detector, in particular between the extractor and the detector; and
a retarding voltage source connected to the retarding grid, and capable of applying a retarding potential N to said retarding grid allowing the electrons reaching the detector to be retarded and stopped.

The electron detector generally allows all or some of the emitted electrons to be counted. Thus, an electron counting means is generally associated with the detector or included in the detector.

According to one embodiment, the detector comprises an electron multiplier, for example, a channel electron multiplier, or even a microchannel plate.

Preferably, the device comprises a vacuum chamber, preferably an ultra-vacuum chamber (that is, between 10⁻⁶ and 10⁻⁹ Pa), with the vacuum chamber being capable of accommodating at least the electron emitter, all or part of the item of equipment for determining the electrical emission potential, all or part of the electron detector, and optionally all or part of the electron extractor. This can be a conventional vacuum chamber (in which the vacuum is formed by a vacuum pump, or even an ultra-vacuum pump) or a sealed enclosure containing a getter.

Preferably, the device further comprises at least one sealed bushing, said electrical bushing being adapted to sealably electrically connect the inside and the outside of the vacuum chamber and being electrically insulated, typically corresponding to a resistivity that is greater than or equal to 10¹⁸ Ω·cm. This typically can be a sapphire bushing.

The electrical bushing allows connections, in particular electrical connections, to be passed between the system to be measured, which is not disposed in the vacuum chamber, and the elements disposed in the vacuum chamber, and more generally between the elements disposed in the vacuum chamber and the elements outside the vacuum chamber.

At least one electrical connection means adapted to electrically connect the system and the vacuum chamber passes through said sealed bushing.

In the case of high resistances, the resistance measurements can be falsified by the circulation of leakage currents that travel on the surface of the system to be measured, for example, through moisture and/or surface contaminants, the resistance of which is less than that of the system. In order to eliminate the leakage currents, the measurement device comprises a housing capable of containing the system to be measured and/or to be connected to the system to be measured. A housing is defined as a protective means configured to reduce the leakage current and/or to distribute the potential around the system to be measured. The housing can be electrically connected to the detector, so as to allow a differential measurement.

A second aim of the invention is a method for determining the resistance of a system implementing the device according to the invention, the method comprising the following steps:

a step of connecting the system to the electrical connection means of the device;
a step of emitting electrons for a potential difference value E applied to the terminals of the device;
a step of measuring the current intensity Iₑ passing through the system, for the potential difference value E, said measuring step comprising measuring the intensity of the current Iₘₑₛ flowing between the emitter and the detector when the emitted electrons are not slowed down before reaching the detector, so that the measured current Iₘₑₛ corresponds to the current Iₑ passing through the system;
a step of determining the electrical emission potential Vₑ of the electron emitter for the potential difference value E;
a step of computing the resistance R_{S} of the system to be measured, provided by the equation

R_{S}=[E−Vₑ]/Iₑ.

It should be noted that the electrons are emitted by the electron emitter, that the intensity of the current flowing between the emitter and the detector is measured by the detector, and that the electrical emission potential is determined by the item of equipment capable of determining the electrical emission potential of the electron emitter.

According to one embodiment, the step of determining the electrical emission potential Vₑ of the emitter comprises:

a step of applying a limit retarding potential value N_{L} to the item of equipment that is sufficient to stop the electrons reaching the detector, so that the measured intensity Iₘₑₛ at the detector decreases to a value I₀ (with I₀ corresponding to the detection limit);
the desired electrical emission potential Vₑ being equal to the limit retarding potential value N_{L}.
with the step of measuring the intensity of the current Iₑ being carried out for a zero retarding potential N.

This embodiment is designed for a device for which the item of equipment that is capable of determining the electrical emission potential Vₑ of the electron emitter comprises a retarding grid disposed between the emitter and the detector, in particular between the extractor and the detector, and a retarding voltage source connected to the retarding grid, and capable of applying a retarding potential N to said retarding grid allowing the electrons reaching the detector to be retarded and stopped.

### BRIEF DESCRIPTION OF THE FIGURES

Further features and advantages of the invention will become apparent from the following description, which is provided by way of a non-limiting illustration and with reference to the appended figure:

FIG. 1 shows an example of a device for determining electrical resistance according to the invention.

### DETAILED DESCRIPTION OF THE INVENTION

### Measurement Device

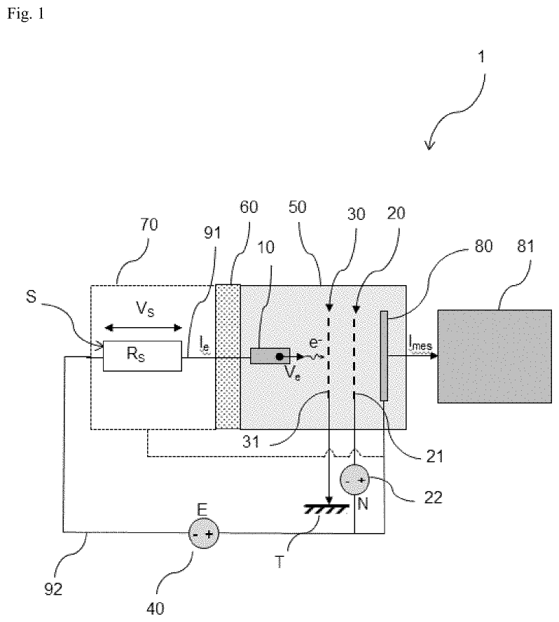

FIG. 1 shows an example of a device for determining electrical resistance according to the invention.

The device shown comprises:

a field effect electron emitter 10 capable of emitting an electron current when the electrical potential Vₑ of the electron emitter is higher than a threshold value V_{L};
an item of equipment 20 capable of determining the electrical potential Vₑ of the electron emitter;
an electron extractor 30;
a voltage source 40 adapted to apply a potential difference E to the device and to generate an electric field at the emitter 10;
an electron detector 80 capable of detecting all or some of the electrons emitted by the electron emitter and associated with (or comprising) an electron counter 81 so as to measure the intensity of the current Iₘₑₛ flowing between the emitter and the detector;
a vacuum chamber 50 capable of accommodating at least the electron emitter 10, all or part of the item of equipment 20, of the electron extractor 30, and of the electron detector 80;
a housing 70 adapted to accommodate the system S to be measured: the housing shown is electrically connected to the detector 80 and therefore to the counter 81, thus allowing a differential measurement to be taken;
an electrical bushing 60 adapted to sealably connect the inside and the outside of the vacuum chamber 50.

Furthermore, the system S, for which the electrical resistance R_{S} is to be determined and which is placed outside the vacuum chamber in the ambient environment, is electrically connected to the device by a first electrical connection 91 between a terminal of the system S and the electron emitter 10, and a second electrical connection 92 between another terminal of the system S and the detector 80. Thus, the current flowing between the emitter and the detector can also pass through said system. The electrical connections conventionally can be cables and/or electrical connections. The first electrical connection can pass through the electrical bushing 60.

The end of the emitter 10 must be at least partially conductive.

The electron flow has kinetic energy eVₑ, where e is the charge of the electron.

The voltage source 40 must be stable, preferably exhibiting stability of 10⁻³ (1 V for 1,000V).

A field emission (or cold emission) electron emitter is an electron source that comprises an emitter material with geometry or conformation that allows a high electric field to be reached when it is subjected to an electrical potential, with the electric field being of the order of 1 V/mm. Under the effect of such an electric field, electrons pass through a potential barrier by the tunnel effect from the Fermi level, at ambient temperature and are emitted by the material. Applying the electric field to the material can be combined with heating the material, in order to obtain a Schottky emission, which allows the electrical extraction potential of the electrons to be reduced.

The emitter material generally comprises a conducting wire (metal or semiconductor), an end of which is shaped as a tip. The most common material is tungsten.

Alternatively, the emitter material can comprise a conducting wire (for example, a carbon wire), one end of which is shaped as a tip, and a crystal made of an insulating material, for example, made of celadonite, halloysite, hematite, deposited on the conductive tip (without completely covering it so that the tip is at least partially conductive). The diameter of the tip can be 10 μm, or even a few μm. The dimensions of the crystal can be of the order of μm and its thickness can be of the order of ten nanometers, for example, 50 nm.

Again alternatively, the emitter material can comprise a conducting wire, one end of which is shaped as a tip, and the tip is machined to form a plate. A crystal made of an insulating material is deposited on the plate (without completely covering it so that the tip is at least partially conductive). The plate can have a diameter ranging between 5 and 50 μm or even a hundred μm. The crystal made of an insulating material can have a width (and/or length) of less than 100 nm, preferably ranging between 10 and 100 nm, for example, of 50 nm and a thickness that is less than or equal to 50 nm, preferably ranging between 1 and 50 nm, for example, 10 nm. The plate can exhibit roughness, comparable to the thickness of the crystal, so that simply depositing the crystal on the plate, combined with the roughness thereof allows a conducting/vacuum/insulating assembly to be formed, in which the vacuum is formed by the spaces between the asperities of the plate (conducting) and the crystal (insulating).

The emitter material forms a cathode (generally called “cold cathode”).

The electron extractor 30 is adapted to extract the electrons from the emitter toward the detector. The extractor is illustrated in the form of an extraction grid 31 forming an anode, and configured to generate an electric field when an electrical extraction potential is applied thereto. Thus, the electrons are emitted toward said extraction grid and toward the detector. The emitter is negatively biased with respect to the extractor and the extraction electrode is grounded T.

The illustrated item of equipment 20 comprises:

a retarding grid 21 disposed between the emitter 10 and the detector 80, and more specifically between the extraction grid 31 and the detector 80;
a retarding voltage source 22 connected to the retarding grid, and capable of applying a retarding potential N to said retarding grid allowing the electrons reaching the detector to be retarded and stopped.

The retarding voltage source 22 must be stable, preferably exhibiting stability of 10⁻³ (1 V for 1,000V).

The item of equipment can comprise one or more retarding grids disposed one after the other on the path of the electrons originating from the emitter, with said retarding grids being disposed between the emitter 10 and the detector 80, each retarding grid being connected to its own voltage source, to allow an energy analysis of the electrons, until the emission of secondary electrons at the output of the series of retarding grids is suppressed.

The set of retarding grid(s) and retarding voltage source(s) can form a retarding field electron energy analyzer.

Alternatively, another type of retarding field energy analyzer (RFEA) can be implemented.

Again alternatively, another energy analyzer can be implemented. For example, it can be a hemispherical sector analyzer (HSA).

The electron detector 80 generally allows all or some of the emitted electrons to be counted. Thus, an electron counting means 81 is generally associated with the detector or included in the detector.

The electron detector 80 can be made up of (or include) an electron multiplier.

An electron multiplier can be formed by placing a perforated or porous plate, for example, a lead glass plate, between an input electrode and an output electrode, and by providing a continuous electric field between the electrodes. When incident electrons strike the input electrode and collide with the surfaces inside the plate, electrons, sometimes called “secondary electrons”, are produced. The secondary electrons are accelerated by the electric field toward the output electrode and collide with other surfaces inside the plate in order to produce more secondary electrons, which in turn can produce more electrons when they accelerate through the plate. Consequently, an electron cascade can be produced when the secondary electrons accelerate through the plate and collide with more surfaces, with each collision being able to increase the number of secondary electrons. A relatively strong electronic pulse can be detected at the output electrode.

The electron detector 80 can be a microchannel plate (known as “MCP”), or a double microchannel plate.

A microchannel plate is an electrical charge amplifier device comprising an array of microchannels, for example, cylindrical and hollow microchannels. Each microchannel, which can act as an independent electron multiplier, has an inner wall surface formed by an electron emitting and conducting layer. The plate is biased by a bias voltage. When incident electrons enter a microchannel, they collide with the surface of the wall and cause a plurality of secondary electrons to be emitted that are accelerated by the bias voltage. The emitted electrons will in turn strike the wall and cause other electrons to be emitted, therefore cascade amplification occurs.

The electron detector 80 can be a microsphere plate (known as “MSP”), or a double microsphere plate.

A microsphere plate is an electrical charge amplifier device comprising a plate made up of microscopic spheres that have electron conducting and emitting surfaces. The spheres are assembled and bonded together, for example, by compression and sintering. The plate is biased by a bias voltage. When incident electrons collide with the surfaces of the spheres, they cause a plurality of secondary electrons to be emitted that are accelerated by the bias voltage across the gaps defined by the spheres. The emitted electrons will in turn strike other spheres and cause other electrons to be emitted, therefore cascade amplification occurs.

Alternatively, the detector can be an electron multiplier with discrete dynodes.

Preferably, the detector is a tubular electron multiplier or “channel electron multiplier”, sometimes called “Channel PhotoMultiplier” or “CPM”.

The detector is associated with (or includes) a counting device, for example, a counting electronics unit 81. An electron counting electronics unit, for example, at the output of a channel electron multiplier, is an electronics unit known to a person skilled in the art, which generally allows signal discrimination to be performed and which provides a signal 0-1 (TTL) at the output in order to be able to count collisions.

The vacuum chamber 50 preferably is an ultra-vacuum chamber (that is, between 10⁻⁶ and 10⁻⁹ Pa), capable of accommodating at least the electron emitter 10, the retarding grid 21, the extraction grid 31 and the electron detector 80.

The counting electronics unit 81 is generally disposed outside the vacuum chamber.

The vacuum chamber can be constructed from standard metal ultra-vacuum components, connected to a high vacuum pump (with metal seals to provide sealing).

Alternatively, the vacuum chamber can be formed by a sealed enclosure (for example, a glass tube) containing a getter pump or a “gas trap”. It should be noted that a getter pump is a fixing pump in which the gas contained in the enclosure is mainly fixed by chemical combination with a getter, allowing a vacuum to be formed in said enclosure. The getter is usually a metal or a metal alloy in solid form or deposited in thin layers.

The electrical bushing 60 allows the inside and the outside of the vacuum chamber to be sealably connected. The bushing is electrically insulated so as to avoid leakage currents. Preferably, the resistivity of the bushing at 300 K is at least 10¹⁸ Ω·cm. It can be a bushing with an alumina ceramic insulator (sapphire), or other bushings known in the ultra-vacuum field. The first electrical connection 91 passes through said sealed electrical bushing.

Other electrical bushings can be provided, in particular to sealably connect the retarding grid 21 and the retarding voltage source 22, as well as the extraction grid 31 and the ground T, or even the detector 80 to the counting means 81, and also to allow through the second electrical connection 92.

An electrical bushing particularly allows the system to be measured, which is not disposed in the vacuum chamber, and the elements disposed in the vacuum chamber to be electrically connected.

In the case of high resistances, the resistance measurements can be falsified by the circulation of leakage currents that travel on the surface of the system to be measured through moisture and/or surface contaminants, the resistance of which is less than that of the system. In order to eliminate the leakage currents, the measurement device can comprise a housing 70 capable of containing the system to be measured and/or to be connected to the system to be measured. The housing forms a connection terminal. It is configured to reduce the leakage current and/or to distribute the potential around the system to be measured. The housing can be formed by an electrically conductive cage (of the Faraday cage type) capable of containing the system and connected to a housing electrode, with the whole being electrically connected to the detector. The housing can be formed by any other means for connecting the system to be measured to a differential system.

### Method for Determining the Resistance of the System

A method will now be described for measuring the resistance of a system that can be particularly implemented with the measurement device of FIG. 1, and more generally with a measurement device according to the invention.

The measurement method involves emitting electrons and determining the electrical emission potential Vₑ of the electron emitter. The electrons are emitted for a potential difference value E allowing an electric field to be generated at the electron emitter. The potential difference value E must be sufficient to obtain a significant electron counting rate and to generate a current for which the intensity Iₘₑₛ can be measured at the detector. When the circuit between the device and the system to be measured S is closed, and the electrons are not retarded between the emitter and the detector, the current Iₘₑₛ measured at the detector is also the current Iₑ that passes through the system S. Measuring the current Iₘₑₛ allows the value of the electrical resistance of the system (S) to be computed.

Initially, the retarding potential N is set to 0 volts.

The gain of the detector and the electronic counting range are adjusted so as to be able to measure a current intensity per the lowest possible count.

The potential difference is increased up to the value E, which allows a significant counting rate, and therefore a significant measured current intensity Iₘₑₛ, to be obtained.

A first step involves measuring the intensity of the current Iₘₑₛ by virtue of the electron detector 80 associated with the counting electronics unit 81, for this potential difference E, and to do so with a zero retarding potential N.

In this case, the electrons are not retarded and even less so stopped and the current Iₑ passing through the system is equal to the measured current Iₘₑₛ at the detector.

In order to measure the emission potential Vₑ, the second step involves applying a retarding potential N_{L} (limit retarding potential) to the item of equipment 20 (retarding grid 21 illustrated in FIG. 1) that is sufficient for retarding the electrons until they are stopped.

On the device illustrated in FIG. 1, the retarding potential N is varied by virtue of the retarding voltage source 22 so that the electrons are slowed down and then stopped. Thus, an increasingly small flow of electrons reaches the detector 80 and the measured intensity Iₘₑₛ at the detector decreases to a value I₀, with I₀ corresponding to the detection limit, for N equal to N_{L}. At this value N_{L} of retarding potential, the counting electronics unit 81 no longer count any electrons.

This value N_{L} of the retarding potential measures the kinetic energy divided by the electron charge for the electrons emitted by the field emitter, and is therefore equal to the desired emission potential Vₑ.

The resistance R_{S} of the system to be measured is equal to the voltage V_{S} at the terminals of the system divided by the intensity of the current Iₑ passing therethrough.

The resistance R_{S} of the system to be measured S is therefore provided by the equation:

R_{S}=(E−Vₑ)/Iₑ=(E−N_{L})/I_{mes[N=0]} Math. 1

### Determined Resistance Range

Depending on the electron detector that is used, the electron counting rate at ambient temperature is between 1 c/s and 10⁸ c/s, i.e., between approximately 10⁻¹⁹ and 10⁻¹¹ A. For such current values, the inventors have determined that a typical value of the emission potentials Vₑ for a field emitter is between 10 and 1,000V.

The equation Math.1 shows that determining the resistance R_{S} of the system requires determining (E−Vₑ). This means that E must be significantly distinct from Vₑ. For example, E can be substantially equal to double Vₑ so that (E−Vₑ) is of the order of Vₑ, i.e., between 10 and 1,000V. With such a base, the measurement range of the resistance R_{S} is between 10 V/10⁻¹¹ A and 1,000V/10⁻¹⁹ A, that is, between 10¹² and 10²² Ohms depending on the electron detector, the field emitter and the electronics unit used.

The relative uncertainty of the measured resistance R_{S} is related to the relative uncertainty on E, Vₑ, E−Vₑ and that on Iₑ. The measurement of (E−Vₑ) can critically depend on the measurement of the limit retarding potential N_{L}, which determines Vₑ. Measurement accuracy can be promoted by using one or more of the following methods:

increasing the stability of the voltage sources E and N;
limiting the divergence of the electron emission beam;
bringing the emitter and the detector as close as possible to each other so as to be able to detect as many emitted electrons as possible (and improve the measurement accuracy of the current intensity at the detector);
limiting the geometric imperfections of the retarding grid;
taking into account the detection efficiency of the detector;
using a bushing with very high impedance (for example, made of sapphire, the resistivity of which is greater than or equal to 10₁₈ Ohm);
using a structure for protecting the system to be measured (housing) adapted to limit or even eliminate the leakage current.

Unless otherwise indicated, the various embodiments, examples and alternative embodiments that have been described can be combined together.

Furthermore, the present invention is not limited to the embodiments described above but extends to any embodiment falling within the scope of the claims.

The invention particularly can be applicable in:

characterizing insulating materials;
measuring high electrical resistance values;
manufacturing voltmeters for very high impedance;
manufacturing ammeters for very low current.

1. A device for determining the electrical resistance of a system (S), said device comprising:
a field effect electron emitter capable of emitting electrons when the electrical emission potential Vₑ of the electron emitter is higher than a threshold value with the emitting end of said emitter being at least partially conductive;
an item of equipment capable of determining the electrical emission potential Vₑ of the electron emitter;
a voltage source adapted to apply a potential difference E to the device and to generate an electric field at the emitter;
an electron detector capable of detecting all or some of the electrons emitted by the electron emitter so as to measure the intensity of the current Iₘₑₛ flowing between the emitter and the detector; and
electrical connection means adapted to electrically connect the system (S) and the device in such a way that the current flowing between the emitter and the detector can also pass through said system.

2. The device as claimed in claim 1, further comprising an electron extractor configured to extract the electrons from the emitter toward the electron detector, with the extractor being disposed between the emitter and the detector.

3. The device as claimed in claim 2, the electron extractor comprising an extraction electrode or an extraction grid disposed between the emitter and the detector and configured to generate an electric field when an electrical extraction potential is applied thereto.

4. The device as claimed in claim 3, the extraction electrode or the extraction grid being connected to a ground terminal (T).

5. The device as claimed in claim 1, the item of equipment comprising an electron energy analyzer,

6. The device as claimed in claim 1, the item of equipment comprising:
a retarding grid disposed between the emitter and the detector; and
a retarding voltage source connected to said retarding grid, and capable of applying a retarding potential N to said retarding grid allowing the electrons reaching the detector to be retarded and stopped.

7. The device as claimed in claim 1, the detector comprising an electron multiplier, for example, a channel electron multiplier, or even a microchannel plate.

8. The device as claimed in claim 1, further comprising an electron counting means associated with or included in the detector.

9. The device as claimed in claim 1, further comprising a vacuum chamber capable of accommodating at least the electron emitter, all or part of the item of equipment, all or part of the electron detector, and optionally all or part of the electron extractor.

10. The device as claimed in claim 9, further comprising a sealed bushing, said electrical bushing being adapted to sealably electrically connect the inside and the outside of the vacuum chamber and being electrically insulated, with at least one electrical connection means passing through said sealed bushing.

11. The device as claimed in claim 1, further comprising a housing, the system to be measured (S) being connected to, and/or disposed in, said housing, the housing being configured to reduce the leakage current and/or distribute the potential around the system to be measured, the housing being able to be electrically connected to the detector so as to allow a differential measurement.

12. A method for determining the resistance of a system (S) implementing the device as claimed in claim 1, the method comprising the following steps:
a step of connecting the system (S) to the electrical connection means of the device;
a step of emitting electrons for a potential difference value E applied to the terminals of the device;
a step of measuring the current intensity Iₑ passing through the system (S), for the potential difference value E, said measuring step comprising measuring the intensity of the current Iₘₑₛ flowing between the emitter and the detector when the emitted electrons are not slowed down before reaching the detector, so that the measured current Iₘₑₛ corresponds to the current Iₑ passing through the system;
a step of determining the electrical emission potential Vₑ of the electrons emitted for the potential difference value E;
a step of computing the resistance R_{S} of the system (S) to be measured, provided by the equation:
R_{S}=[E−Vₑ]/Iₑ.

13. The determination method as claimed in claim 12, implementing the device as claimed in claim 12, wherein the item of equipment comprises:
a retarding grid disposed between the emitter and the detector; and
a retarding voltage source connected to said retarding grid, and capable of applying a retarding potential N to said retarding grid allowing the electrons reaching the detector to be retarded and stopped;
the step of determining the emission voltage Vₑ comprising:
a step of applying a retarding potential value N_{L} to the item of equipment that is sufficient to stop the electrons reaching the detector, so that the measured intensity Iₘₑₛ at the detector decreases to a value I₀ corresponding to the detection limit of the detector;
the desired electrical emission potential Vₑ being equal to the limit retarding potential value N_{L};
with the step of measuring the current Iₑ being carried out for a zero retarding potential N.
